(19) United States
(12) Patent Application Publication
(10) Pub. No.: US 2008/0019082 A1
(43) Pub. Date: Jan. 24, 2008

(54) Docking station for a portable device

(75) Inventors: Michael Krieger, Miami Beach, FL (US); Kevin Ellsworth, Hollywood, FL (US)

Correspondence Address: VENABLE LLP, P.O. BOX 34385, WASHINGTON, DC, 20043-9998, US

(73) Assignee: Black & Decker, Inc., Newark, DE (US)

(21) Appl. No.: 11/706,990

(22) Filed: Feb. 16, 2007

Related U.S. Application Data
(60) Provisional application No. 60/774,242, filed on Feb. 17, 2006.

(51) Int. Cl. H05K 7/00; H01Q 1/24; H02J 7/00; H04B 1/034

(52) U.S. Cl. 361/679; 320/115; 343/702; 455/128

(57) ABSTRACT

A docking station for a portable device, which is electrically coupleable to an external power supply, comprising a base having a cup-shape to facilitate portability of the docking station and its ease of use. The docking station includes a docking cavity for docking the portable device. A mating connector disposed in the docking cavity provides electrical interconnection between the docking station and the portable device and a flexible support between the base and the docking cavity provides for electrical coupling between the mating connector and the external power supply.

This application claims the priority of Provisional Application No. 60/774,242, filed on Feb. 17, 2006, the subject matter of which is incorporated herein by reference.

### FIELD OF THE INVENTION

The present invention generally relates to a docking station and more particularly relates to a docking station for a portable device.

### DESCRIPTION OF THE PRIOR ART

Various docking stations are known for portable devices. For example, U.S. Pat. No. 6,591,085 issued to Grady describes a modular docking unit for an iPod® that can engage and disengage from various types of supporting power/charging adapters, including a pedestal, a cigarette lighter adapter, a wall mount and a desk mount. The modular docking unit includes an FM transmitter and power supply/charging circuitry electrically coupled to the iPod®. The power supply/charging circuitry transmits electrical power through the modular docking unit to power/charge the iPod®. The power/charging circuitry thereby provides electrical power for charging the iPod® battery. The FM transmitter transmits the audio content played by the iPod® for reception and play by a remote radio receiver, such as a car radio. A coupling means in a docking cavity connects the iPod® with the circuitry of the FM transmitter and power/charging assembly.

A docking station having a flexible support for holding a media player is also known. Belkin® Corporation offers a device called Tunebase® for iPod® mini (Part # F8V7098), which operates through a cigarette lighter outlet within the car. Tunebase® has a holder with a flexible-steel neck for positioning the iPod® mini safely while driving. While mounted in the Tunebase®, the iPod® mini is powered and charged simultaneously.

With the ever increasing availability of various portable devices, there exists a continuing need for improving functionalities and operation of docking stations.

### SUMMARY OF THE INVENTION

Briefly, according to one aspect of the invention, a docking station for a portable device, which is electrically coupleable to an external power supply, comprises a base having a cup-shape to facilitate portability of the docking station and its ease of use. The docking station includes a docking cavity for docking the portable device. A mating connector disposed in the docking cavity provides electrical interconnection between the docking station and the portable device, and a flexible support between the base and the docking cavity provides for electrical coupling between the mating connector and the external power supply. A base adjustment sleeve can also be used with the docking station of the present invention for adjusting a physical dimension of the cup-shaped base as necessary.

According to another aspect, the docking station comprises a base that attaches to a device holder via a support, e.g., a flexible support, for holding the portable device. A docking cavity is removably attachable to the device holder. The docking cavity can be integrated with the housing of the portable device or include a clip device that is used to removably attach the docking cavity to the device holder.

According to still another aspect of the present invention, a docking station accommodates differently sized portable devices via a fitting adapter. The fitting adapter is insertable into the docking cavity to support holding portable devices of different sizes by providing for expansion or restriction of the docking cavity. A retainer disposed on the docking cavity can be used for securing the fitting adapter against the docking station.

According to some of the more detailed features of the invention, the docking station includes a transmitter for transmitting signals generated by the portable device to a remote receiver. According to yet another aspect of the invention, an antenna for the docking station includes a conductor that radiates radio frequency signals and a suction-cup that is attached along the length of the antenna conductor for positioning the antenna on a surface, preferably in close proximity of the antenna of the remote receiver.

According to other more detailed features of the invention, power circuitry coupled to the external power supply energizes the portable device. The power circuitry can include charger circuitry for charging one or more batteries of the portable device. A control circuitry controls one or more functions of the docking station, including a user interface function or a data exchange function between the portable device and the docking station. Among others, the mating connector supports a port interface comprising one or more of a universal serial bus (“USB”) port, a Firewire® port, an iPOD® port or a personal digital assistant (“PDA”) port interface.

### BRIEF DESCRIPTION OF THE DRAWINGS

FIG. 1 is a docking station having a cup-shaped base and a flexible support for holding a portable device in a docking cavity according to one embodiment of the present invention.

FIG. 2 shows a fitting adapter for accommodating different size portable devices.

FIG. 3 shows an antenna for the docking station of FIG. 1 according to another aspect of the invention.

FIG. 4 illustrates another embodiment of a docking station with a removable docking cavity.

FIGS. 5A-5C illustrate an exemplary embodiment of coupling a device holder with a device clip attached to a portable device according to the present invention;

FIG. 6 illustrates an exemplary embodiment of a base for a docking station of FIG. 4; and

FIG. 7 illustrates an exemplary block diagram of a base of a docking station according to the present invention.

### DESCRIPTION OF THE INVENTION

In describing the exemplary embodiments of the present invention illustrated in the drawings, specific terminology is employed for the sake of clarity. However, the invention is not intended to be limited to the specific terminology so selected. It may be understood that each specific element includes all technical equivalents that operate in a similar manner to accomplish a similar purpose.

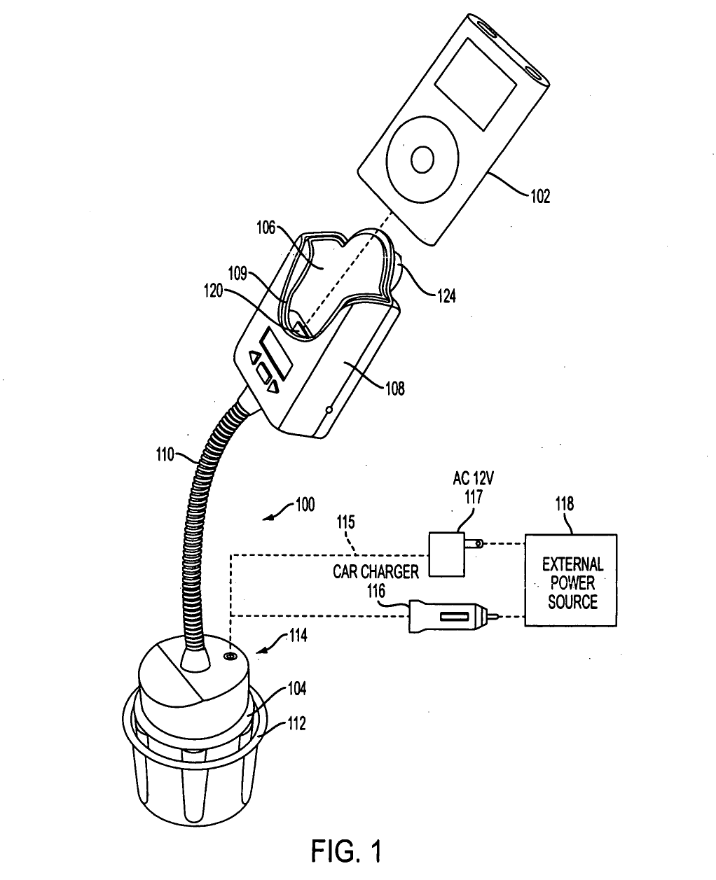

FIG. 1. illustrates an exemplary embodiment of a docking station 100 for a portable device 102. Examples of portable device 102 include a media (e.g., audio, image or video) player, a PDA, a computing device, a positioning system device, a cellular phone, or any other suitable portable electronic device. An exemplary media player can be an iPod® audio player offered by Apple® Corporation.

As shown, according to one embodiment of the invention, the docking station 100 has a cup-shaped base 104 and a docking cavity 106. The base 104 which has a cup shape can comprise any of a wide variety of rounded, concave bowl shapes characterized by a hollow interior portion, which can have a rounded circular shape or a rounded non-circular horizontal cross section, including substantially conic, cubic, or cylindrical shape. FIG. 1 shows the base 104 being substantially cylindrical having a rounded circular horizontal cross section. But, the rounded shape of the base 104 can comprise sides that create a non-circular cup-shape design. The docking cavity 106 comprises an unfilled space within a mass, for example, a hollowed-out space created by injection molding of a suitable material, such as plastic. The docking cavity 106 is defined by a housing 108 used for docking or otherwise positioning the portable device in the docking station. The cup-shaped base 104 according to this embodiment is attached to docking cavity housing 108 via an elongated flexible support 110, which is made from a known suitable material, such as metal or plastic. The cup-shaped base 104 may be an injection molded piece made from a single or multiple suitable material. The cup shape of the base 104 facilitates portability of the docking station. In one application, the cup-shaped base can be inserted into a cup holder, for example, in a vehicle. A base adjustment sleeve 112 can be used in conjunction with the cup-holder base 104 to accommodate various sizes for different applications. By inserting the cup-shaped base 104 into the base adjustment sleeve 112, base 104 may fit more snugly in a cup holder of increased diameter.

The elongated flexible support 110 is bendable, adjustable, and movable, thus allowing a user to position the docking cavity 106 to a desired location. The elongated flexible support 110 substantially maintains its shape and allows the portable device 102 to be supported and positioned at the desired location. This configuration of the invention allows the user to place the portable device 102 at a location that may, for example, be at a safe distance that allows for the portable device to be manipulated while driving an automobile or a moving vehicle. Thus, the flexible support 110 allows for adjustably positioning the docking cavity 106 in the perimeter of the cup-shaped base 104, for example, in a safe position when inside a vehicle. Optionally, a front lip spacer 109 is placed on the front lip of the cavity housing to further secure the portable electronic device.

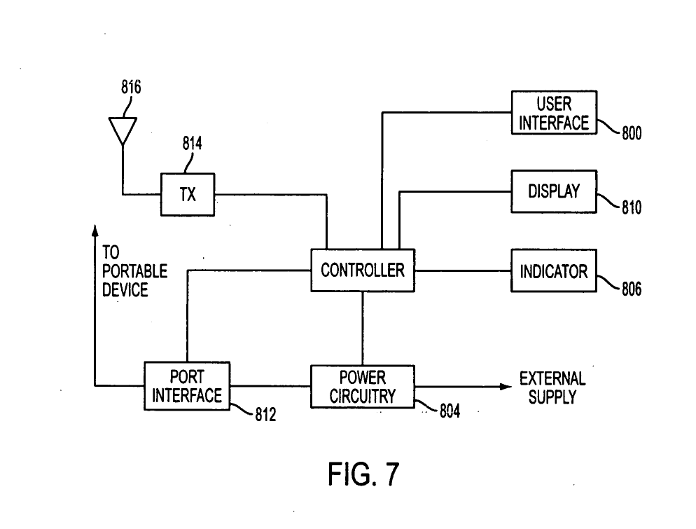

In one embodiment of the invention, some or all of the circuitry of the docking station 100 is enclosed within the docking cavity housing 108. Such functional circuitry can include power, control, processor, as well as transmitter circuitry. The transmitter allows audio played by the portable device 102 to transmit on a selected channel and be heard on a properly tuned radio receiver. The processor provides circuitry for managing user interface functionality, including display and controls for setting the transmit channel of the transmitter. In addition, power or charger circuitry, as applicable, can energize the portable device 102. For example, a power jack 114 disposed on the cup-shaped base 104 is used for supplying power via an external power source 110. The external power source can be a cigarette lighter adapter (“CLA”) 116 or a wall cube power supply 117, an AC-to-DC power supply, with each supply having its corresponding cords and power plug for insertion into the power jack 114 of the docking station 100 to provide external power to the docking station for energizing the portable device 102. In one embodiment, wires that electrically interconnect the power supplied from the external power source 118 are passed through the cup-shaped base 104 and elongated flexible support 110 to the portable device 102 via a mating connector 120 in the docking cavity 106, as further described later. As such, the docking station acts as a straight-through power conduit to the portable device, which uses its own battery charger circuit to provide charge energy to the portable device. In another embodiment, the docking station itself can be equipped with charger circuitry for charging the portable device batteries. As described later in connection with FIG. 7, functional circuitry of the docking station can also be positioned in the base 104 instead of the docking cavity housing 108.

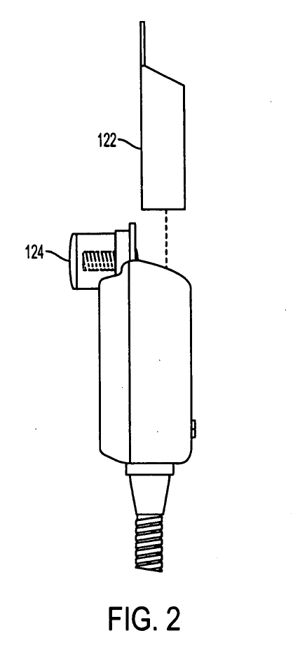

The docking station 100 according to this aspect of the present invention can also accommodate different size portable devices via appropriately designed fitting accessories or adapters, which can constrict or enlarge the docking space needed for accommodating different sizes. For example, through one or more corresponding adapters, the docking station can accommodate various sizes of iPod® players, which are offered in standard, “mini,” “nano” and “shuffle” sizes. In one embodiment, the docking station accommodates, a standard iPod® by inserting it into the docking cavity directly without any fitting adapter. For accommodating smaller sized iPods®, suitably sized fitting adapters are used, which reduce the cavity size. The fitting adapters are inserted into the docking cavity to create appropriately sized cavities that accommodate corresponding iPods®. FIG. 2 shows fitting adapter 122 that provides a smaller sized cavity for accommodating, for example, an iPod® mini. Conversely, the cavity of the docking station can be expanded by a fitting adapter. For example, in another embodiment (not shown), the docking cavity can accommodate the iPod® mini directly without a fitting adapter. Under this arrangement, a standard iPod® fitting adaptor can be inserted in the docking cavity with an enlarged docking cavity to accommodate the larger size of the standard iPod®.

After the fitting adapter is inserted into the docking cavity, a retainer is used to secure it to the docking station. In the exemplary embodiment shown in FIG. 2, the retainer is a retainer knob 124 that is engaged with the fitting adapter 122 via a thread that runs through the back side of the docking cavity housing 108. When screwed through the thread, the retainer knob 124 is moved forward to exert pressure against an inserted fitting adapter, via a round tab, to securely hold it in place.

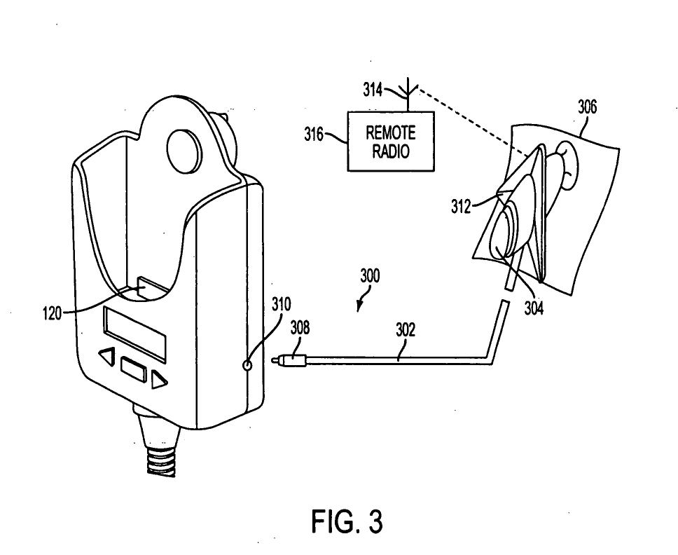

FIG. 3 shows an antenna 300 for the docking station 100 according to another aspect of the present invention. The antenna 300 is suitable for use with the transmitter of the docking station which transmits audio of a media player to a remote receiver. The antenna 300 includes an antenna conductor 302 that radiates radio frequency (RF) signals to the remote receiver. A suction-cup 304 that is attached along the length of the antenna conductor 302 positions the antenna on a surface 306. Thus, the antenna 300 is surface-attachable via the suction cup 306. In the embodiment of FIG. 3, the conductor 302 is terminated at one end by an antenna plug 308 that is insertable into an antenna jack 310 disposed on the docking station 100, e.g., on the side of the docking cavity housing. The other end of the antenna is terminated at a molded piece that comprises wing-shaped piece 312. Wing-shaped piece 312 is attachable to the suction cup 304, which allows for attaching the antenna 300 on a suitable surface 306, such as the windshield of a vehicle. The suction cup 304 according to this aspect of the present invention facilitates convenient positioning of the antenna 300 in close proximity to an antenna 314 of a remote radio receiver 316, thereby improving reception quality of the audio applied to the docking station at the remote receiver 316.

Referring back to FIG. 1, when the portable device 102 is placed in the docking cavity 106, either directly or through a corresponding fitting adapter, the mating connector 120 in the docking cavity of the docking station 100 electrically engages with a complementary mating connector of the portable electronic device 122. The mating connector 120 includes interface contacts for transfer of analog, digital or power signals between the docking station 100 and the portable electronic device 122. Power contacts of the mating connector 120 provide electrical power when the portable device is placed in the docking cavity 106. Thus, through the power contacts of the mating connector 120, the docking station 100 supplies power or charge energy to the batteries of the electronic device 102. Audio contacts of the mating connector 120 apply audio signals generated by the portable device 102 to the FM transmitter of the docking station 100. Through the audio contacts, the FM transmitter of the docking station receives audio signals from the portable electronic device for transmission to a remote FM receiver on a selected channel. In one embodiment, the mating connector 120 comprises a single connector, which supports one or a plurality of interfaces, such as USB and Firewire®, including a plurality of audio, data and power contacts.

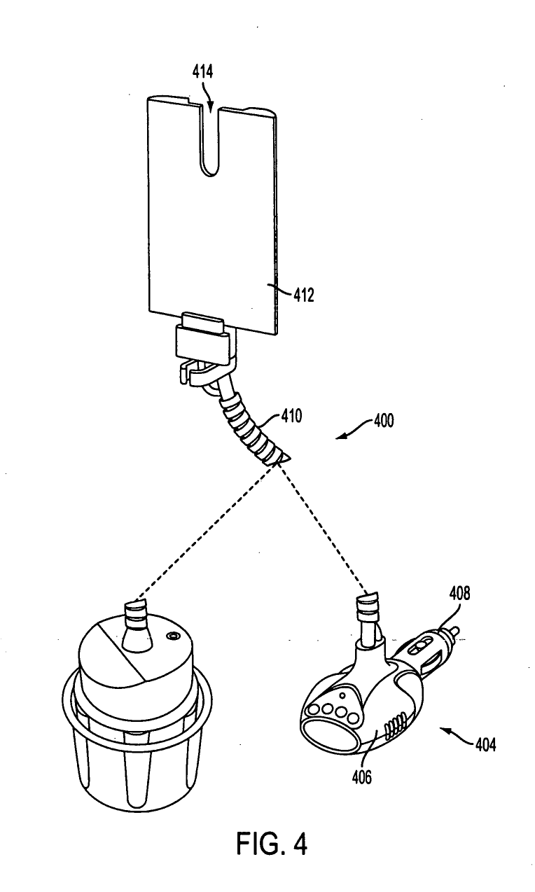

FIG. 4 illustrates an exemplary embodiment of a docking station 400 according to another aspect of the present invention. This aspect of the invention relates to a docking station that is configured as a CLA device that supports a portable device via a removable docking cavity. The docking station 400 includes a base 404 attached to one end of an elongated flexible support 410. The other end of flexible support 410 is connected to a device holder 412, which is configured to hold a removable docking cavity, as further described below. The base 404 according to this embodiment comprises a housing 406 having a CLA plug 408 that attaches to a CLA socket (not shown), as further described in connection with FIG. 4. It should be noted that, although this embodiment of the invention is described in terms of the CLA base 404, the base of the docking station 400 under this aspect of the present invention can also comprise a cup-shaped base, as described in connection with FIG. 1.

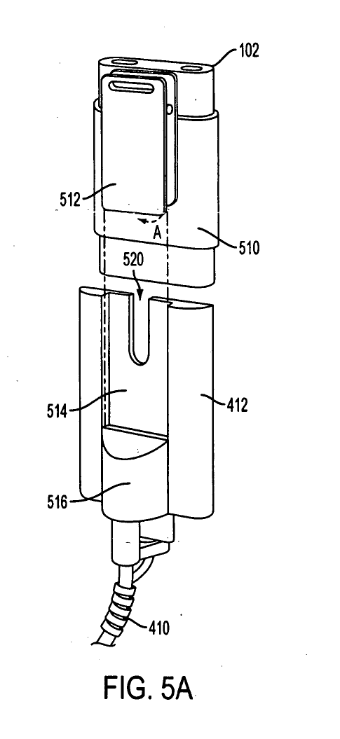

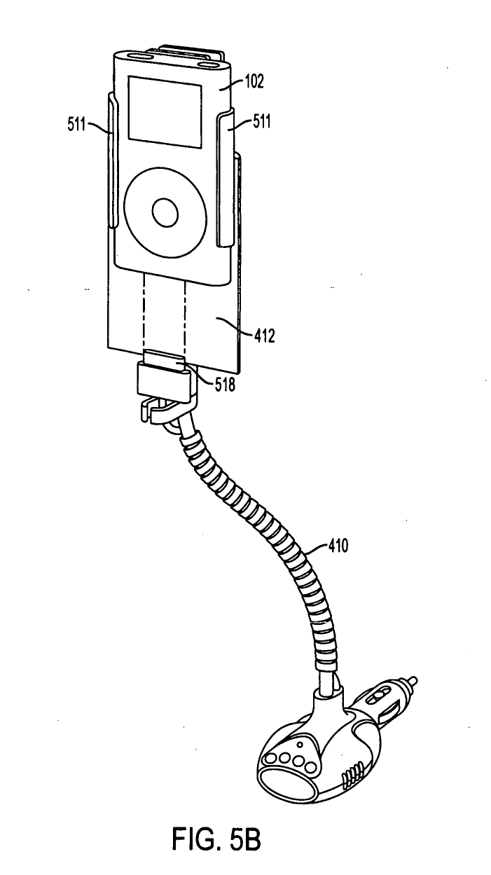

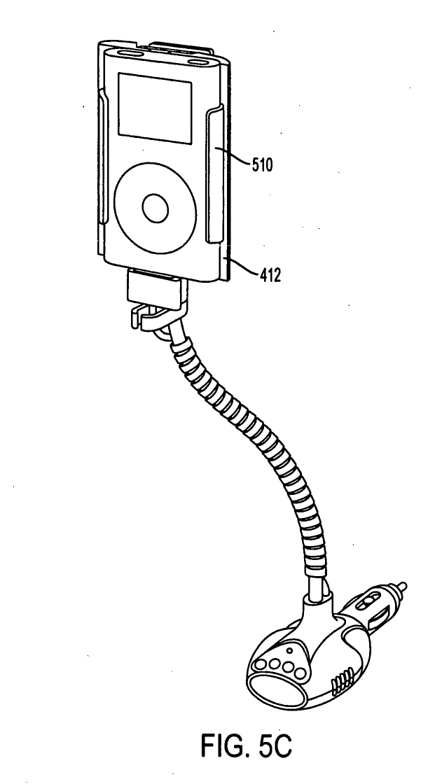

As shown in FIG. 4, the base 404 (CLA or alternatively a cup-shaped base) is coupled to the elongated flexible support 410 for supporting the device holder 412 of the removable docking cavity housing at a desired location. The device holder 412, which can be made of molded plastic or any other suitable material, has a substantially flat front surface with a receiving slot 414 in the form of a notch that accommodates reception and removal of the docking cavity housing, as shown in FIGS. 5A and 5B.

As shown in FIGS. 5A and 5B, the docking cavity under this embodiment of the invention comprises a removable docking cavity 510. In one embodiment, the removable docking cavity 510 is adapted to create a grip around the portable device to provide a robust support system. The removable docking cavity 510 shown in FIGS. 5A and 5B includes ledges 511 on opposing sides of the docking cavity 510 that creates a grip around the portable device 102. Under this arrangement, the portable device 102 is slideable into the removable docking cavity 510 and guided by the ledges until becoming fully inserted, as shown in FIG. 5C. Once fully inserted, the ledges hold the portable device 102 in the removable docking cavity 510. The portable device 102 can be removed by sliding it out of the docking cavity. The backside of the docking cavity includes a spring-loaded belt clip 512 used to attach an inserted portable device on a belt or other apparel worn by a person.

On the back side of the device holder 412 (shown in FIG. 5A), a properly sized depression 514 is disposed to accommodate the coupling and uncoupling of the removable docking cavity. When inserting the portable device 102 into the device holder 412, the removable docking cavity 510 slides into the receiving slot 520 on the back of the device holder 412 and slides along the depression grooves, which guide the removable docking cavity 510 during insertion and removal. Under this arrangement, the elongated flexible support 410 attaches to the backside of the device holder 412 via a neck mount 516 comprising a molded extrusion. As shown in FIG. 5B, the neck mount 516 is designed to carry a properly positioned mating connector 518 and connection interface for electrically connecting the docking station 400 to the portable device. The flexible support 410 is dimensioned to carry the electrical wiring necessary for electrically connecting the portable device to the docking station 400 when the portable device attaches to the docking station 400. As described above, the mating connector 518 between the docking station 400 and the portable device 102 can comprise a variety of port interfaces, including a USB, a Firewire®, an iPOD®, or any other suitable port interface. The mating connector 518 engages with a complementary connector of the portable device to electrically connect the docking station with the portable device. FIG. 5C illustrates the removable docking cavity 510 being fully inserted into the device holder 412.

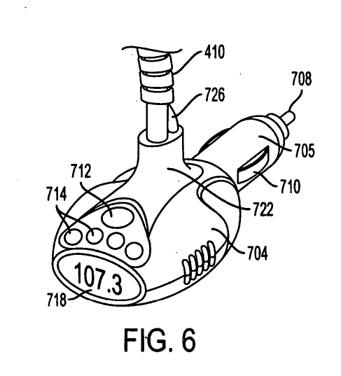

FIG. 6 illustrates an exemplary embodiment of a base 704 according to the present invention. The base 704 includes a CLA plug 706 for insertion into an external CLA socket. As depicted, the CLA plug 706 includes a center protruding pin 708 that, upon insertion, electrically couples to a corresponding center contact of the external socket (not shown). Elongated spring contacts 710 are disposed on the sides of the CLA plug 706 to provide a ground connection with the side walls of the external CLA socket. When inserted, the CLA plug 708 is adapted to receive power from an external DC source, which may be, for example, the battery of a vehicle or any other type of suitable external DC source.

The exterior of the base 704 includes indicator 712 and depressible user interface buttons 714, allowing the user to control the docking station and functions of the portable device. The base includes a power LED indicator to indicate when the plug of the base is fully inserted into the external CLA socket and is receiving power from the external DC source.

The base also includes a digital display 718 that indicates the radio frequency being used by the FM transmitter and to display the radio frequency while scanning. The base also includes a coupling mold 722 that is adapted to couple the base with the elongated flexible support 410 and the wire 726. The coupling mold physically secures the base to the elongated flexible support. The coupling mold also receives the wire for connection to the internal circuitry, as discussed below.

FIG. 7 illustrates an exemplary block diagram of the docking station of the present invention. A block 802 comprising power circuitry is attached to an external power supply that provides electrical power for powering various functionalities of the docking station, including the transmitter and control functions, as well as energizing the portable device. A controller 804 controls user interface functions such as indicator 806, user interface 808, and display 810. The controller 804 is adapted to receive user input, to communicate data and control signals with the portable device as necessary, and to control the functionality of the docking station. The exchanged signals between the docking station and the portable device occur over a suitable port interface 812 such as an iPod®, Universal, USB or Firewire® port interfaces.

Examples of features controlled by the docking station include audio control information (e.g., pause, play, etc.), as well as requesting stored data to be transmitted to the docking station. Examples of control data sent from both the docking station and the portable device include request data, acknowledgement data, device detection data, communication setup data, error data, and other known networking and control data transmitted between devices prior to and during communication.

Another type of data exchanged between the docking station and the portable device is audio, which may be analog or digital. Audio signals generated by the portable device are applied to a transmitter 814 for transmission to the remote radio receiver. The transmitter modulates radio frequency carrier signals, preferably within the commercial band, e.g., AM, FM, S-band, X-band with the analog audio signal to generate radio frequency signals, which are radiated via an antenna 816. The radio frequency signals can be received by an external radio receiver, such as an AM, FM, or satellite band receiver of a car stereo, a home theater system, or any other radio frequency receiver.

The embodiments and examples discussed herein are non-limiting. The invention has been described in detail with respect to preferred embodiments, and it will now be apparent from the foregoing to those skilled in the art that changes and modifications may be made without departing from the invention in its broader aspects, and the invention, therefore, as defined in the appended claims, is intended to cover all such changes and modifications that fall within the true spirit of the invention.

1. A docking station for a portable device electrically coupleable to an external power supply comprising:
a base having a cup-shape;
a housing defining a docking cavity for docking the portable device;
a connector disposed in the housing for providing electrical interconnection between the docking station and the portable device, and
a flexible support connecting the cup-shaped base and the housing, wherein electrical coupling between the mating connector and the external power supply is provided via the flexible support.

2. The docking station of claim 1, further including at least one of a 1) transmitter powered by the external power supply for transmitting signals generated by the portable device to a remote receiver, 2) power circuitry coupled to the external power supply for energizing the portable device, or 3) controller for controlling a function of the docking station, disposed in the cup-shaped base or the cavity housing.

3. The docking station of claim 2, wherein the power circuitry includes a charger circuitry for charging the portable device.

4. The docking station of claim 2, wherein at least the controller is disposed in the cup-shaped base or the housing, and the controller is operative to control at least one of 1) a user interface function, or 2) data exchange function between the portable device and the docking station.

5. The docking station of claim 1, wherein the connector supports a port interface comprising at least one of a USB, Firewire®, a iPOD® port or PDA port interface.

6. The docking station of claim 1, further including a base adjustment sleeve removably coupled to the base to adjust a physical dimension of the base.

7. The docking station of claim 1 further comprising a fitting adapter insertable into the housing to adjust the dimensions of the docking cavity to support holding a portable device.

8. The docking station of claim 7, further including a retainer operatively arranged on the housing for securing the fitting adapter in the housing.

9. A docking station for a portable device electrically coupleable to an external power supply comprising:
a base having a cup-shape;
a device holder attached to the base;
a housing defining a docking cavity for docking the portable device, wherein the housing is removably attachable to the device holder;
a connector attached to the housing providing an electrical interconnection between the docking station and the portable device, and
a support between the base and the housing, wherein an electrical coupling between the connector and the external power supply is provided via the support.

10. The docking station of claim 9, wherein the support comprises a flexible support.

11. The docking station of claim 9, wherein the housing defining the docking cavity comprises a clip device that is used to removably attach the housing to the device holder.

12. The docking station of claim 9 further including at least one of a 1) transmitter powered by the external power supply for transmitting signals generated by the portable device to a remote receiver, 2) power circuitry coupled to the external power supply for energizing the portable device, or 3) controller for controlling a function of the docking station.

13. The docking station of claim 12, wherein the power circuitry includes a charger circuitry for charging the portable device.

14. The docking station of claim 12, wherein the function comprise at least one of a 1) user interface function, or 2) data exchange function between the portable device and the docking station.

15. The docking station of claim 9, wherein the connector supports a port interface comprising at least one of a USB port, Firewire®, iPOD®, or PDA port interface.

16. The docking station of claim 9 further including a base adjustment sleeve for adjusting a physical dimension of the cup-shaped base.

17. An antenna for a docking station that includes a transmitter for transmitting audio of a player to a receiver, comprising:
an antenna conductor that radiates radio frequency signals; and
a suction-cup that is attached along the length of the antenna conductor for positioning the antenna on a surface.
